(19) United States
(12) Patent Application Publication
(10) Pub. No.: US 2012/0182843 A1
(43) Pub. Date: Jul. 19, 2012

(54) DEVICES AND METHODS FOR PROTECTING LASER DIODES FROM ELECTROSTATIC DISCHARGE

(75) Inventor: Michael Lennard, Lyons, CO (US)

(73) Assignee: SEAGATE TECHNOLOGY LLC, Scotts Valley, CA (US)

(21) Appl. No.: 12/970,068

(22) Filed: Jan. 18, 2011

(51) Int. Cl. G11B 13/04; H01S 5/00

(52) U.S. Cl. 369/13.26; 372/38.09; 369/13.32; G9B/13.002

(57) ABSTRACT

In accordance with certain embodiments, an apparatus has a depletion-mode transistor electrically connected to a laser diode. The transistor provides a low impedance path for diverting electrostatic current away from the laser diode. In accordance with certain embodiments, a method for protecting a laser diode from an electrostatic charge includes providing a transistor that is electrically connected to a laser diode and has a drain and a source. The method further includes redirecting the electrostatic charge through a low impedance path from the drain to the source during a powered-on state.

### SUMMARY

Various embodiments of the present invention are generally directed to devices and methods for protecting a laser diode in a storage device from electrostatic discharge.

In accordance with certain embodiments, an apparatus has a depletion-mode transistor electrically connected to a laser diode. The transistor provides a low impedance path for diverting electrostatic current away from the laser diode. In accordance with certain embodiments, a method for protecting a laser diode from an electrostatic charge includes providing a transistor that is electrically connected to a laser diode and has a drain and a source. The method further includes redirecting the electrostatic charge through a low impedance path from the drain to the source during a powered-on state.

These and other features and aspects which characterize various embodiments of the present invention can be understood in view of the following detailed discussion and the accompanying drawings.

### BRIEF DESCRIPTION OF THE DRAWINGS

FIG. 1 illustrates a schematic of a circuit diagram in accordance with various embodiments of the present disclosure.

FIG. 2 illustrates a schematic of a circuit diagram in accordance with various embodiments of the present disclosure.

FIG. 3 illustrates a schematic of a circuit diagram in accordance with various embodiments of the present disclosure.

FIG. 4 illustrates a schematic of a circuit diagram in accordance with various embodiments of the present disclosure.

FIG. 5 illustrates a schematic of a circuit diagram in accordance with various embodiments of the present disclosure.

FIG. 6 illustrates a schematic of a circuit diagram in accordance with various embodiments of the present disclosure.

FIG. 7 illustrates a schematic of a circuit diagram in accordance with various embodiments of the present disclosure.

FIG. 8 illustrates a flowchart of a method for protecting a laser diode from electrostatic discharge.

### DETAILED DESCRIPTION

Laser diodes are susceptible to becoming damaged from electrostatic discharge events. One example includes storage devices utilizing heat assisted magnetic recording (HAMR) and provisioned with a laser diode that supplies a heat source to elevate the temperature of the storage media. Electrostatic discharge can occur during handling, assembling, testing, and operating the storage device.

During operation, while the storage device is powered-on, the head flies above the storage media. The interaction between the head and storage media can cause electrostatic charges to build up and eventually discharge across the head/media interface. This electrostatic build up between the head and storage media is commonly due to tribocharging. If uncontained, an electrostatic discharge (ESD) event can damage the head and components on or near the head, for example, a laser diode utilized in HAMR storage devices.

During handling, assembly, and testing; a circuit containing a laser diode may be subjected to an ESD event created, for example, by human and equipment contact.

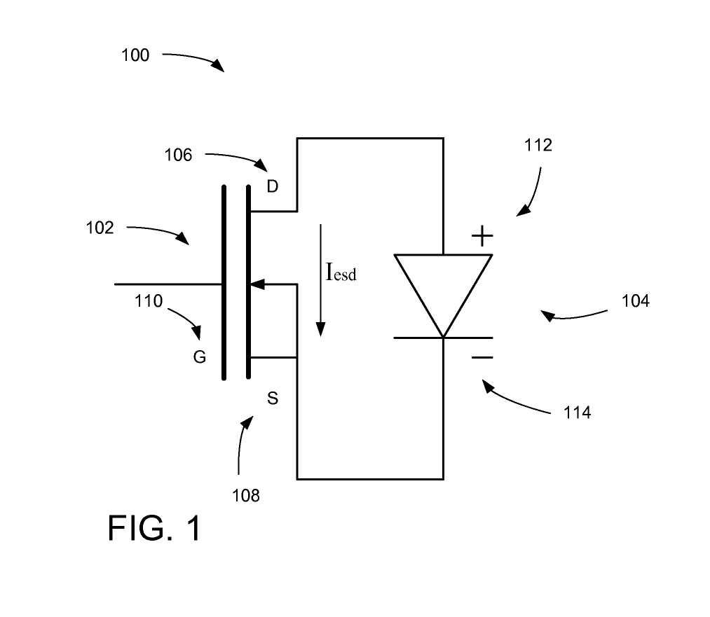

FIG. 1 illustrates a diagram of a circuit 100, which includes a depletion-mode transistor 102 and a laser diode 104. The depletion-mode transistor 102 includes a drain 106, source 108, and gate 110. The laser diode 104 can be a semi-conductor diode that includes an anode 112 and a cathode 114. The transistor 102 is electrically connected across the laser diode 104 and provides a low impedance current path to divert electrostatic current (illustrated as I_{esd}) away from the laser diode 104.

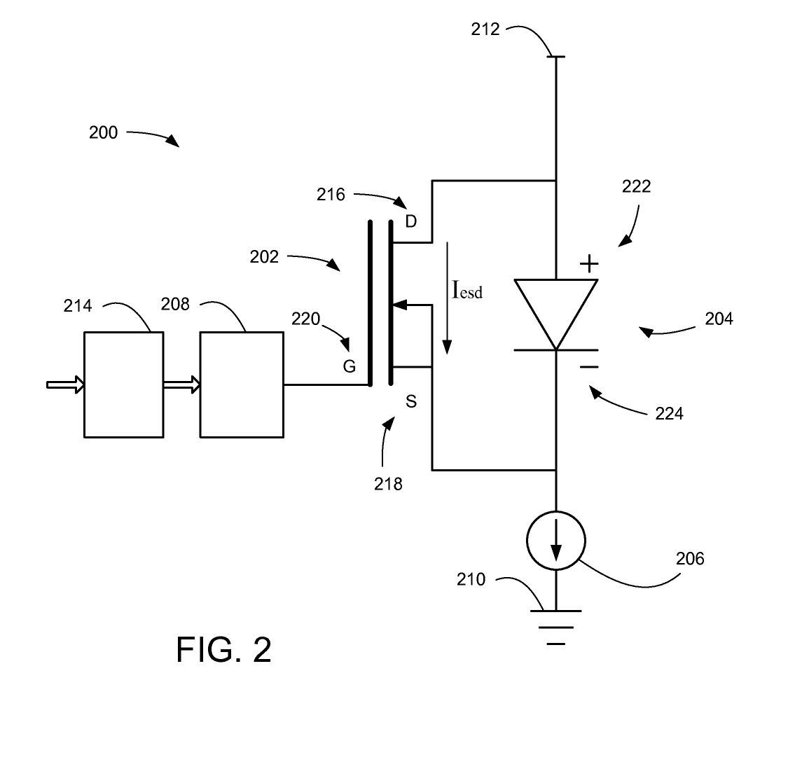

FIG. 2 illustrates a diagram of a circuit 200, which includes a depletion-mode transistor 202, laser diode 204, current source 206, gate driver 208, ground 210, voltage source 212, and head-select input 214. The transistor 202 can be a depletion-mode N-type (shown) or P-type metal oxide semiconductor that includes a drain 216, source 218, and gate 220. The laser diode 204 can be a semi-conductor diode that includes an anode 222 and a cathode 224. The transistor 202 is electrically connected across the laser diode 204.

The transistor 202 provides a low impedance current path from the drain 216 to the source 218. The low impedance path diverts or shunts electrostatic current (illustrated as I_{esd}) away from the laser diode 204 while a storage device is powered-off or powered-on and unselected, thereby protecting the laser diode 204 from electrostatic discharge. The level of impedance is controlled by a gate voltage, which is provided to the transistor gate 220 by the gate driver 208. The gate voltage is controlled by the head-select input 214.

Current flows between the drain 216 and source 218 through the transistor 202 when the gate voltage is equal to or greater than zero and a voltage is applied between the drain 214 to the source 216. As the gate voltage becomes negative, the amount of current that flows through the transistor 202 decreases. When the gate voltage becomes sufficiently negative no current flows. These characteristics allow the transistor 202, when powered-off, to act as a normally-closed switch, thereby diverting electrostatic current away from the laser diode 204. During a powered-on state, the transistor 202 may act as either a closed or open switch. For example, in a HAMR storage device utilizing read/write heads, the storage device may be powered-on but the read/write head may not be selected to read/write—resulting in the transistor 202 acting as a normally-closed switch. If the storage device is powered-on and the read/write head is selected, the transistor acts as an open switch, which allows current to flow through the laser diode 204 allowing the laser diode to be biased into operation.

As shown in FIG. 2, the anode 222 is electrically connected to the voltage source 212 and transistor drain 216; and the cathode 224 is electrically connected to the current source 206 and transistor source 218, thereby providing a current path.

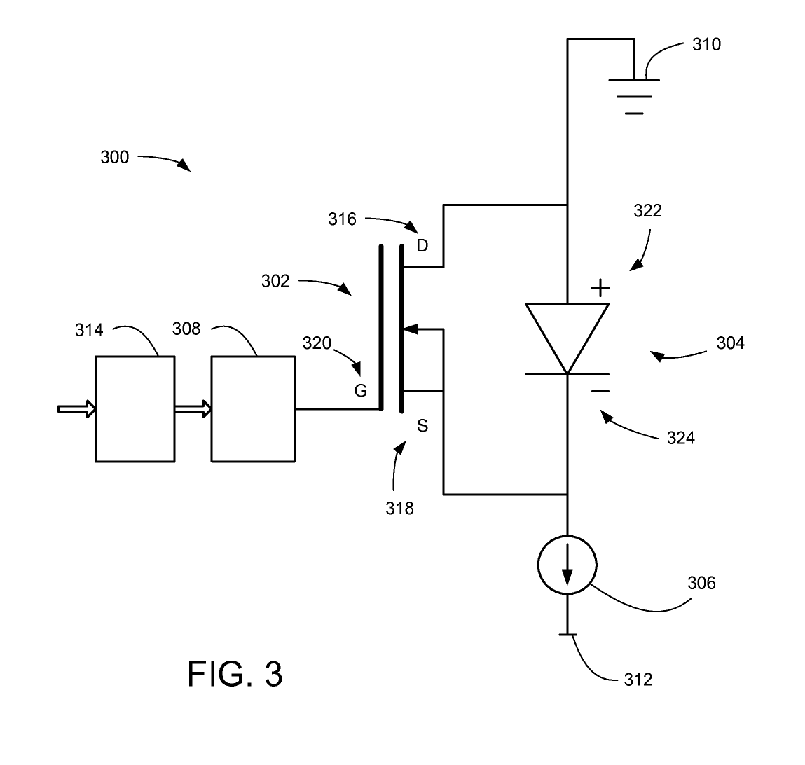

FIG. 3 illustrates a diagram of a circuit 300, which includes a depletion-mode transistor 302, laser diode 304, current source 306, gate driver 308, ground 310, negative voltage rail 312, and head-select input 314. The transistor 302 can include a drain 316, source 318, and gate 320. The laser diode 304 can include an anode 322 and a cathode 324. The transistor 302 is electrically connected across the laser diode 204 and provides a low impedance current path from the drain 316 to the source 318.

As shown in FIG. 3, the anode 322 is electrically connected to the ground 310 and transistor drain 316; and the cathode 324 is electrically connected to the current source 306 and transistor source 318, thereby providing a current sink. Grounding the anode 322 can improve the thermal performance of the laser diode 304 because the anode 322 is a larger structure than the cathode 324 and therefore provides a better heat sink. Also, because the anode 322 can be ground to a head suspension assembly, it is not necessary to provide a trace to a storage device head.

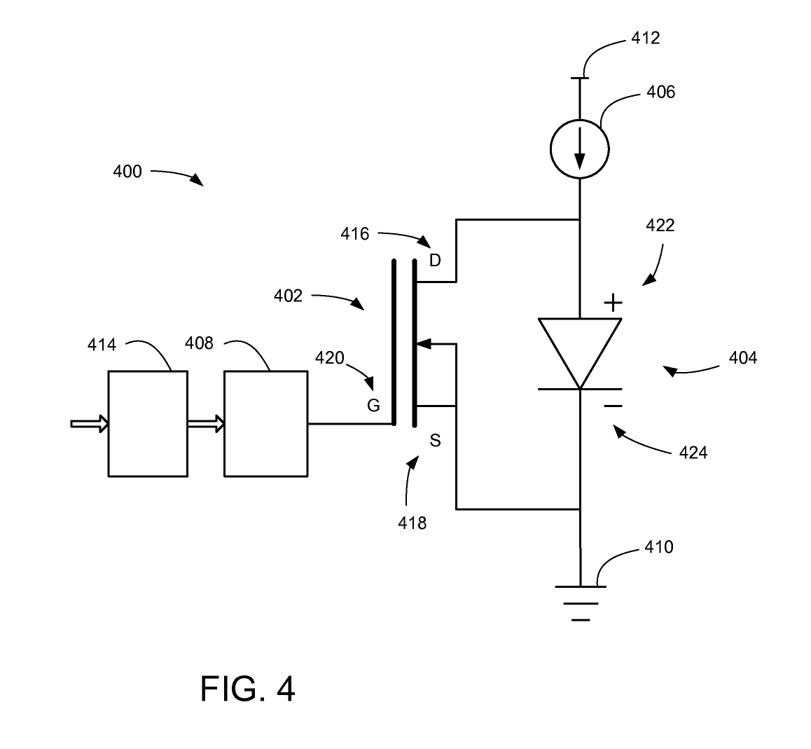

FIG. 4 illustrates a diagram of a circuit 400, which includes a depletion-mode transistor 402, laser diode 404, current source 406, gate driver 408, ground 410, voltage source 412, and head-select input 414. The transistor 402 can include a drain 416, source 418, and gate 420. The laser diode 404 can include an anode 422 and a cathode 424. The transistor 402 is electrically connected across the laser diode 404 and provides a low impedance current path to divert electrostatic current away from the laser diode 404.

As shown in FIG. 4, the cathode 424 is electrically connected to the ground 410 and transistor source 418; and the anode 422 is electrically connected to the current source 406 and transistor drain 416. Because the cathode 424 can be ground to a head suspension assembly, it is not necessary to provide a trace to the storage device head.

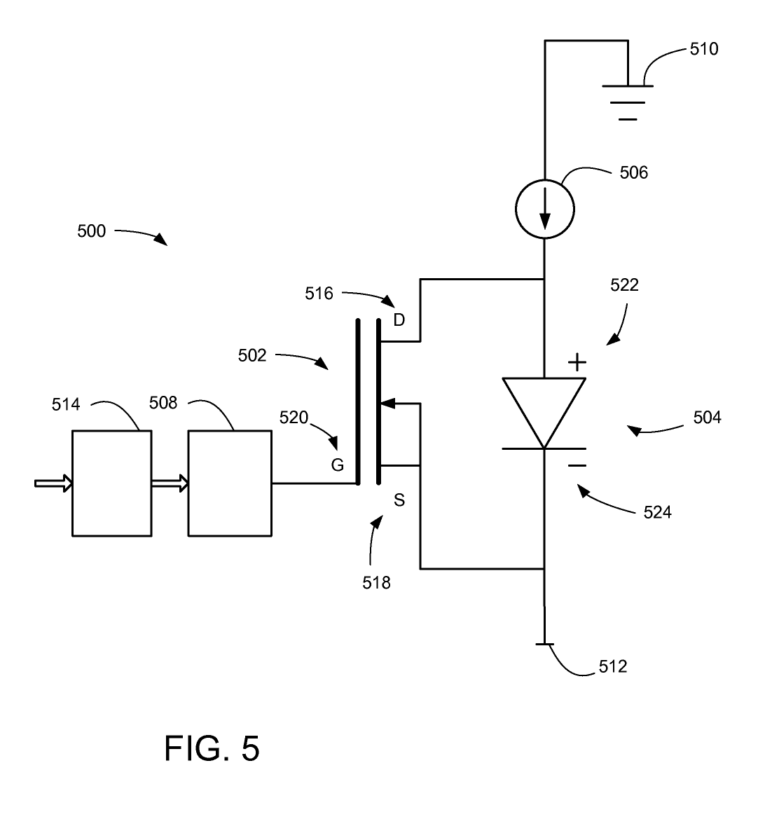

FIG. 5 illustrates a diagram of a circuit 500, which includes a depletion-mode transistor 502, laser diode 504, current source 506, gate driver 508, ground 510, negative voltage rail 512, and head-select input 514. The transistor 502 can include a drain 516, source 518, and gate 520. The laser diode 504 can include an anode 522 and a cathode 524. The transistor 502 is electrically connected across the laser diode 504 and provides a low impedance path current path to divert electrostatic current away from the laser diode 504.

As shown in FIG. 5, the anode 522 is electrically connected to the current source 506 and transistor drain 516; and the cathode 524 is electrically connected to the negative voltage rail 512 and the transistor source 518.

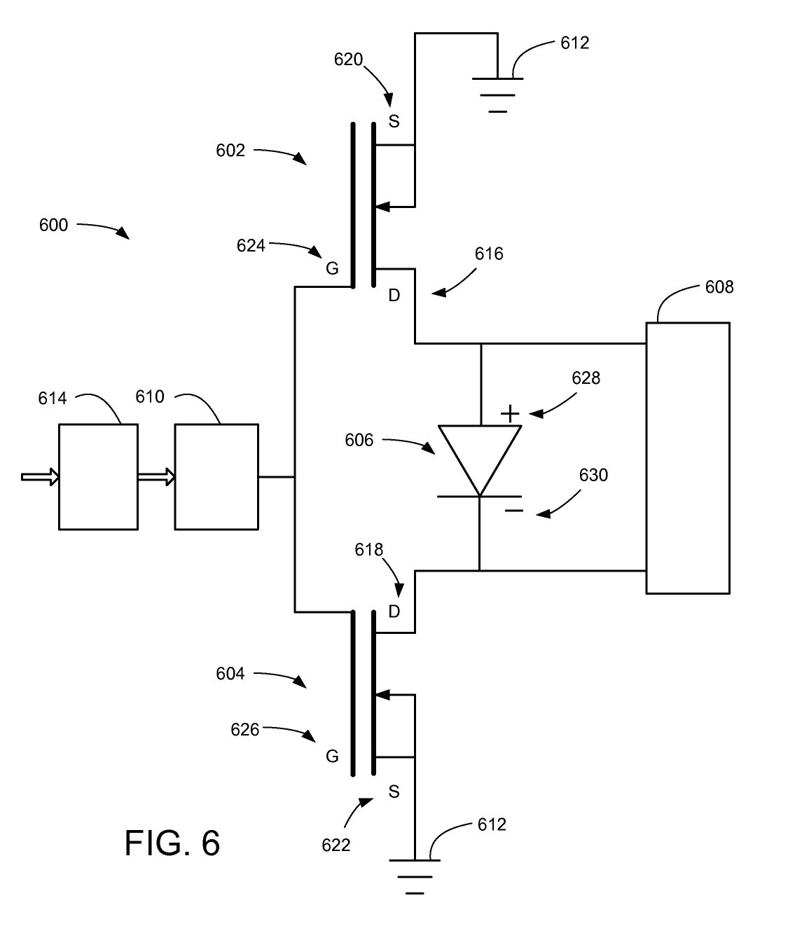

FIG. 6 illustrates a diagram of a circuit 600, which includes a first and second depletion-mode transistor 602 and 604, laser diode 606, bias or differential circuit 608, gate driver 610, ground 612, and head-select input 614. Each transistor includes a drain 616 and 618, source 620 and 622, and gate 624 and 626. The laser diode 606 can include an anode 628 and cathode 630.

As shown in FIG. 6, the anode 628 is electrically connected to the bias circuit 608 and to the first transistor's drain 616; and the cathode 630 is electrically to the bias circuit 608 and to the second transistor's drain 618. When a storage device is off or a head is unselected, the bias circuit 608 goes into a high impedance state, which makes the bias circuit 608 seem invisible to the circuit 600 thereby allowing both sides of the laser diode 606 to be grounded.

In the unpowered state both the anode 628 and cathode 630 are grounded through the transistors 602 and 604. Adding additional transistors in parallel with transistors 602 and 604 further reduces the resistance across the laser diode 606, thereby reducing the level of impedance through the low impedance path that diverts electrostatic currents away from the laser diode 606.

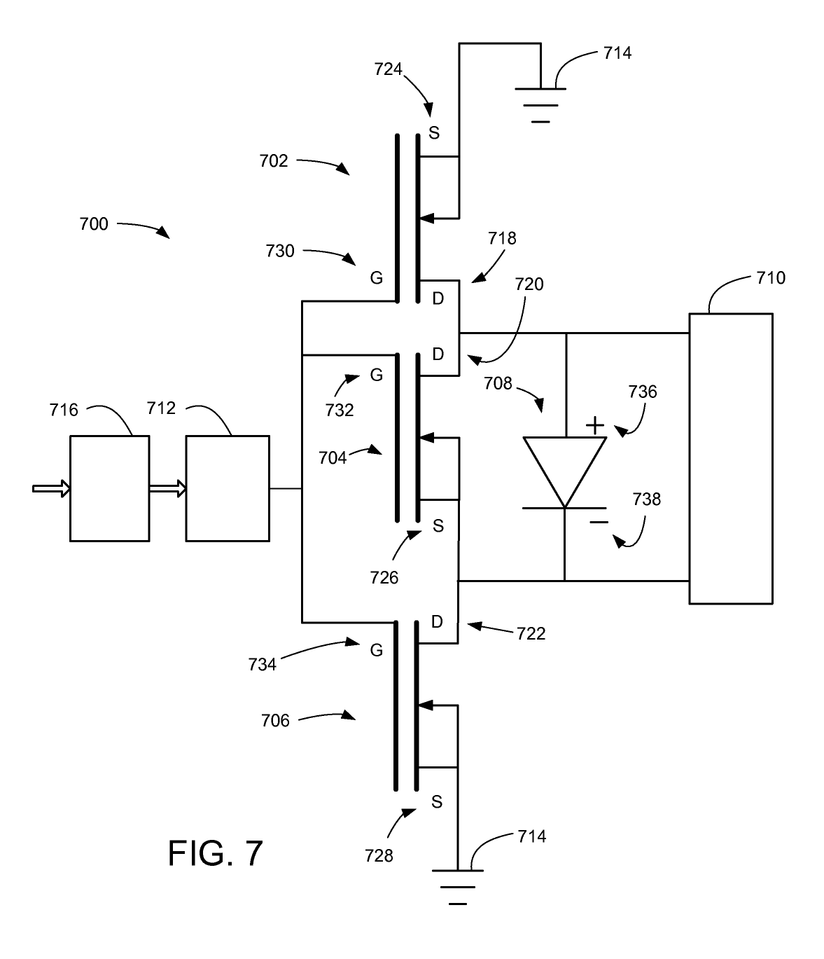

FIG. 7 illustrates a diagram of a circuit 700, which includes a first, second, and third depletion-mode transistor 702, 704, and 706, respectively; laser diode 708; bias or differential circuit 710; gate driver 712; ground 714; and head-select input 716. Each transistor includes a drain 718, 720, and 722; a source 724, 726, and 728; and a gate 730, 732, and 734. The laser diode 708 can include an anode 736 and cathode 738.

As shown in FIG. 7, the anode 736 is electrically connected to the bias circuit 710 and the first and second transistor's drain 718 and 720. The cathode 738 is electrically connected to the bias circuit 710, the second transistor's source 726, and the third transistor's drain 722. In the unpowered or unselected state the anode 736 and cathode 738 are shorted together and both are grounded.

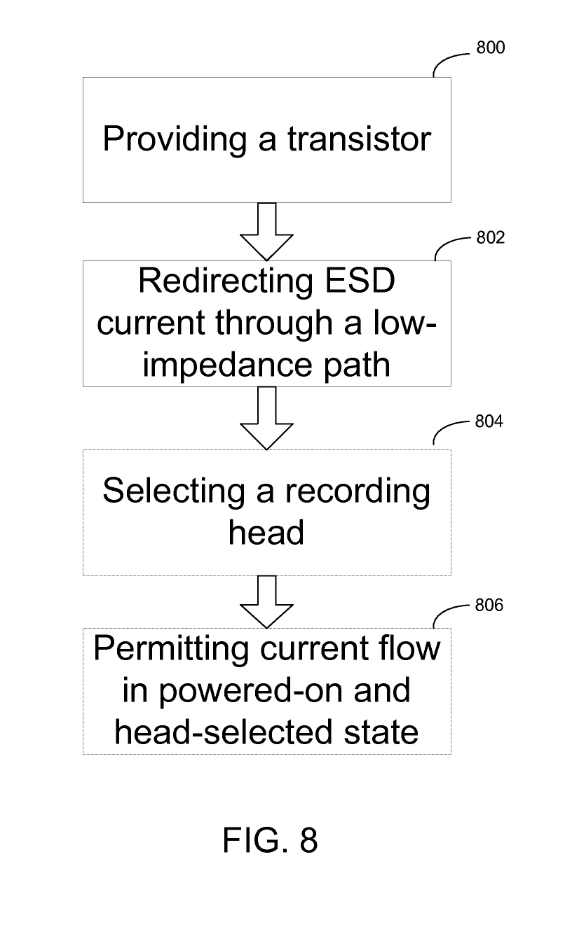

FIG. 8 illustrates a flowchart of a method for protecting a laser diode from electrostatic discharge. The method includes providing a transistor that is electrically connected to a laser diode and has a drain and a source (step 800). The method further includes redirecting the electrostatic charge through a low impedance path from the drain to the source during a powered-on state (step 802). Additional optional steps are shown in boxes having dotted lines. For example, optional step 804 includes selecting a recording head of a storage device. Further, the method could include permitting current to flow through the laser diode when the recording head is selected and the storage device is in the powered-on state (step 806).

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed.

What is claimed is:

1. An apparatus comprising:
a depletion-mode transistor electrically connected to a laser diode, the depletion-mode transistor providing a low impedance path for diverting electrostatic current away from the laser diode while the apparatus is powered-on.

2. The apparatus of claim 1, further comprising:
a gate driver for controlling an input voltage to a transistor gate; and
a recording head selection input signal in electrical communication with the transistor gate driver, the recording head selection input signal communicating either a selected head state or an unselected head state;
wherein the transistor is configured as an open switch during a powered-on, selected head state.

3. The apparatus of claim 2, wherein a laser diode anode is electrically connected to a positive rail.

4. The apparatus of claim 2, wherein a laser diode anode is grounded.

5. The apparatus of claim 2, further comprising:
a differential circuit electrically connected across the laser diode.

6. The apparatus of claim 1, wherein the depletion-mode transistor is an N-type metal-oxide-semiconductor.

7. The apparatus of claim 1, wherein the depletion-mode transistor is a P-type metal-oxide-semiconductor.

8. The apparatus of claim 1, wherein the low impedance path is between a transistor drain and a transistor source.

9. The apparatus of claim 1, further comprising:
at least two transistors electrically connected in parallel.

10. The apparatus of claim 1, wherein the apparatus is a storage device.

11. A method for protecting a laser diode from an electrostatic charge, the method comprising:
providing a transistor electrically connected to a laser diode, the transistor having a drain and a source; and
redirecting the electrostatic charge through a low impedance path from the drain to the source during a powered-on state.

12. The method of claim 11, wherein the laser diode is electrically connected to a plurality of transistors connected in parallel.

13. The method of claim 11, wherein the transistor is a depletion-mode N-type metal-oxide-semiconductor.

14. The method of claim 11, wherein the transistor is a depletion-mode P-type metal-oxide-semiconductor.

15. The method of claim 11, wherein the laser diode is utilized in a storage device and the powered-on state comprises a powered-on storage device.

16. The method of claim 15, and further comprising:
selecting a recording head of the storage device; and
permitting current to flow through the laser diode when the recording head is selected and the storage device is in the powered-on state.

17. An electrostatic discharge (ESD) shunting circuit comprising:
a depletion-mode N-type metal-oxide-semiconductor transistor;
a laser diode electrically connected to the laser diode; and
a low impedance path through the transistor from a transistor drain to a transistor source, the low impedance path diverts ESD current away from the laser diode.

18. The circuit of claim 17, wherein the circuit is implemented in a rotating storage device.

19. The circuit of claim 18, wherein the low impedance path continues to divert ESD current away from the laser diode when the rotating storage device is in a powered-off state.

20. The method of claim 19, wherein the low impedance path continues to divert ESD current away from the laser diode when the rotating storage device is in a power-on state.
